(19) United States
(12) Patent Application Publication
(10) Pub. No.: US 2009/0320756 A1
(43) Pub. Date: Dec. 31, 2009

(54) MICROWAVE PLASMA PROCESSING APPARATUS

(75) Inventor: KOUJI TANAKA, Sendai-Shi (JP)

Correspondence Address: IPUSA, P.L.L.C, 1054 31ST STREET, N.W., Suite 400, Washington, DC, 20007, US

(73) Assignee: TOKYO ELECTRON LIMITED

(21) Appl. No.: 12/487,719

(22) Filed: Jun. 19, 2009

(30) Foreign Application Priority Data
Jun. 25, 2008 (JP) 2008-166347

(51) Int. Cl. C23C 16/54

(52) U.S. Cl. 118/723 MW

(57) ABSTRACT

A disclosed microwave plasma processing apparatus includes a process chamber whose inside may be maintained at a reduced pressure; a susceptor that is provided in the process chamber and holds a substrate; a gas supplying portion configured to supply a gas to the process chamber; a microwave generating portion that generates microwaves; a plasma introducing portion that is arranged to oppose the susceptor and introduces the microwaves generated by the microwave generating portion to the process chamber; and a mesh member arranged between the plasma introducing portion and the susceptor.

### BACKGROUND OF THE INVENTION

1. Field of the Invention

The present invention relates to a microwave plasma processing apparatus where plasma is generated by microwaves in a process chamber and a substrate held inside the process chamber is processed by use of the plasma.

2. Description of the Related Art

Plasma process technology is essential for a semiconductor device fabrication process. In recent years, miniaturization of device elements has been promoted from a demand for highly-integrated large scale integration (LSI) circuits. Along with this, a plasma processing apparatus suitable for such miniaturization is also in high demand. Because a parallel plate or inductively-coupled high frequency plasma processing apparatus, which has been frequently used, has a high electron temperature, a deposited film or an underlying layer after plasma etching may be damaged. Such damage may become a serious problem along with the miniaturization of the device elements. In addition, while a gate insulator made of silicon oxynitride with better insulation properties has been considered as a substitute for a conventional thermally oxidized gate insulator with a decreasing thickness of a gate insulator, the silicon oxynitride film having sufficient insulation properties as the gate insulator cannot be provided by the conventional plasma processing apparatus because of plasma damage.

For this reason, for example, a Radial Line Slot Antenna (RLSA) microwave plasma processing apparatus that can uniformly generate high-density plasma having low electron temperatures has attracted attention (for example, Japanese Patent Application Laid-Open Publication No. 2000-294550). In the RLSA microwave plasma apparatus, microwaves are radiated to a process chamber from the RLSA having plural slots formed in a predetermined pattern through a microwave transmission plate; microwave plasma is generated by a microwave electrical field in the process chamber; and a semiconductor wafer or the like is processed by the plasma.

Microwaves cannot propagate through plasma when an electron density in the plasma is in excess of a cut-off density for the microwaves. As a result, while the plasma can have a high plasma density and a high electron temperature in a plasma excitation region of several millimeters through several tens of millimeters from the transmission plate, the electron temperature decreases to about 1 eV in a plasma diffusion region, which is outside the plasma excitation region. In other words, the microwave plasma processing apparatus can provide plasma with a reduced electron temperature and a high electron density, which makes it possible to reduce damage to the deposited film or the underlying layer after etching. Moreover, because no electrodes are needed in the process chamber, plasma damage to the electrodes, which may cause metal contamination to the deposited film, can be reduced, thereby generally reducing damage to the semiconductor devices.

However, there is still a demand for further reduced damage to the devices even if the microwave plasma processing apparatus causes less damage to the devices compared with the conventional plasma processing apparatuses.

The present invention has been made in view of the above, and is directed to a microwave plasma processing apparatus that can reduce damage to a substrate by microwave plasma and thus deposit a high quality film with a reduced defect density.

### SUMMARY OF THE INVENTION

In order to achieve the above objective, according to a first aspect of the present invention, there is provided a microwave plasma processing apparatus including a process chamber whose inside may be maintained at a reduced pressure; a susceptor that is provided in the process chamber and holds a substrate; a gas supplying portion configured to supply a gas to the process chamber; a microwave generating portion that generates microwaves; a plasma introducing portion that is arranged to oppose the susceptor and introduces the microwaves generated by the microwave generating portion to the process chamber; and a mesh member arranged between the plasma introducing portion and the susceptor.

According to a second aspect of the present invention, there is provided a microwave plasma processing apparatus according to the first aspect, further including a temperature adjusting portion that adjusts a temperature of the mesh member.

According to a third aspect of the present invention, there is provided a microwave plasma processing apparatus according to a first or a second aspect, further including an electric power source that applies a voltage to the mesh member.

According to a fourth aspect of the present invention, there is provided a microwave plasma processing apparatus according to any one of the first through the third aspects, wherein the gas supplying portion includes a first gas passage formed inside the gas supplying portion; plural first gas discharging holes that are in communication with the first gas passage and open in a first direction; a second gas passage formed inside the gas supplying portion, the second gas passage being separated from the first gas passage; and plural second gas discharging holes that are in communication with the second gas passage and open in a second direction different from the first direction.

According to a fifth aspect of the present invention, there is provided a microwave plasma processing apparatus according to any one of the first through the fourth aspects, wherein the mesh member is arranged between the gas supplying portion and the susceptor.

According to a sixth aspect of the present invention, there is provided a microwave plasma processing apparatus according to any one of the first through the fourth aspects, wherein the mesh member is arranged between the plasma introducing portion and the gas supplying portion.

According to a seventh aspect of the present invention, there is provided a microwave plasma processing apparatus according to the first through the third aspects, wherein the gas supplying portion comprises a first member and a second member, wherein the first member includes a first gas passage formed inside the first member; and plural first gas discharging holes that are in communication with the first gas passage and open in a first direction, and wherein the second member includes a second gas passage formed inside the second member; and plural second gas discharging holes that are in communication with the second gas passage and open in a second direction different from the first direction.

According to an eighth aspect of the present invention, there is provided a microwave plasma processing apparatus according to the seventh aspect, wherein the first member, the mesh member, and the second member are arranged in this written order in a direction from the plasma introducing portion to the susceptor between the plasma introducing portion and the susceptor.

According to a ninth aspect of the present invention, there is provided a microwave plasma processing apparatus according to the seventh aspect, wherein the mesh member, the first member, and the second member are arranged in this written order in a direction from the plasma introducing portion to the susceptor between the plasma introducing portion and the susceptor.

According to a tenth aspect of the present invention, there is provided a microwave plasma processing apparatus according to the seventh aspect, wherein the first member, the second member, and the mesh member are arranged in this written order in a direction from the plasma introducing portion to the susceptor between the plasma introducing portion and the susceptor.

According to an eleventh aspect of the present invention, there is provided a microwave plasma processing apparatus according to any one of the first through the fourth and the seventh through the tenth aspects, wherein the mesh member is placed on the susceptor so that the mesh member does not contact the substrate placed on the susceptor.

### BRIEF DESCRIPTION OF THE DRAWINGS

FIG. 1A is a schematic view illustrating a microwave plasma processing apparatus according to a first embodiment of the present invention;

FIG. 1B is a plan view of a Radial Line Slot Antenna used in the microwave plasma processing apparatus illustrated in FIG. 1A;

FIG. 2A is a plan view illustrating one surface of a shower plate used in the microwave plasma processing apparatus illustrated in FIG. 1A

FIG. 2B is a cross-sectional view taken along line A-A in FIG. 2A;

FIG. 2C is a plan view illustrating another surface of the shower plate illustrated in FIG. 2A

FIG. 3A is a schematic view illustrating a microwave plasma processing apparatus according to a second embodiment of the present invention;

FIG. 3B is a plan view illustrating a mesh plate used in the microwave plasma processing apparatus illustrated in FIG. 3A;

FIG. 4 is a schematic view illustrating a microwave plasma processing apparatus according to a third embodiment of the present invention;

FIG. 5 is a schematic view illustrating a microwave plasma processing apparatus according to a fourth embodiment of the present invention;

FIG. 6 is a schematic view illustrating a microwave plasma processing apparatus according to a fifth embodiment of the present invention; and

FIG. 7 is a modification example of the shower plate used in a microwave plasma processing apparatus according to an embodiment of the present invention.

### DETAILED DESCRIPTION OF THE PREFERRED EMBODIMENTS

According to an embodiment of the present invention, there is provided a microwave plasma processing apparatus that can reduce damage to a substrate by microwave plasma and thus deposit a high quality film with a reduced defect density.

Referring to the accompanying drawings, preferred embodiments of the present invention will be explained. In the drawings, the same or corresponding reference marks are given to the same or corresponding members or components, and unnecessary repetition of explanation is omitted. The drawings are illustrative of the invention, and there is no intention to indicate scale or relative proportions among the members or components. Therefore, the specific size should be determined by a person having ordinary skill in the art in view of the following non-limiting embodiments.

### A First Embodiment

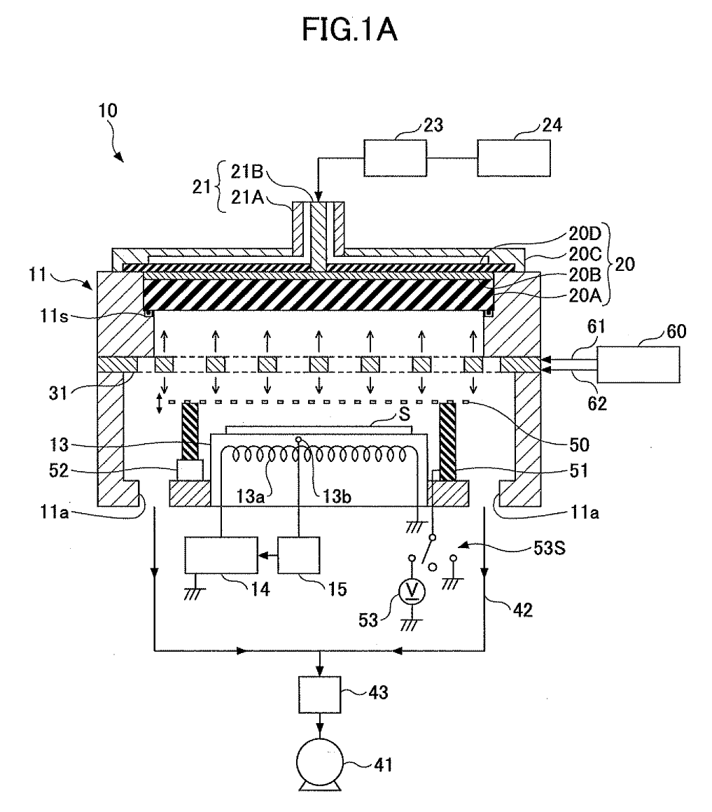

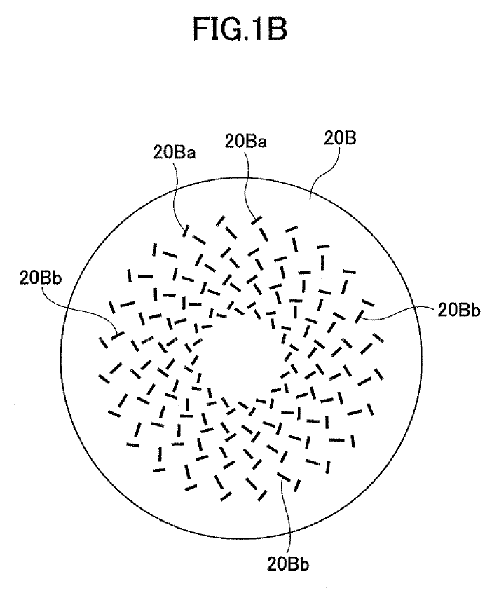

FIGS. 1A and 1B are schematic views illustrating a microwave plasma processing apparatus 10 according to a first embodiment of the present invention. The microwave plasma processing apparatus 10 according to this embodiment is configured as a plasma assisted film deposition apparatus where a silicon film such as an amorphous silicon film, a polycrystalline silicon film, or the like is deposited on a substrate.

Referring to FIG. 1A, the microwave plasma processing apparatus 10 includes a process chamber 11 and a susceptor 13 provided in the process chamber 11 in order to hold a substrate S by use of an electro-static chuck and the like.

The process chamber 11 may preferably be made of aluminum (Al), or austenitic stainless steel including Al. When the process chamber 11 is made of the austenitic stainless steel, a protection film of aluminum oxide is preferably formed on an inner wall surface by an oxidation treatment. A transfer opening (not shown) through which the substrate S is transferred into or out from the process chamber 11 and a gate valve (not shown) for opening/closing the transfer opening are provided in a side wall of the process chamber 11.

At the bottom of the process chamber 11, at least two or preferably three evacuation ports 11a are formed axisymmetrically with respect to the center of the substrate S on the susceptor 13. A gas supplied to the process chamber 11 from a shower plate 31 (later described) is evacuated through the evacuation ports 11a by an evacuation apparatus 41. In addition, a pressure control valve 43 is provided in a duct 42 that connects the process chamber 11 to the evacuation apparatus 41, thereby controlling an inner pressure of the process chamber 11 in a range from about 4 Pa (0.03 Torr) through about 133 Pa (10 Torr).

A thermocouple 13b and a heater 13a such as a heating wire are mounted in the susceptor 13. The heater 13a is electrically connected to an electric power source 14, from which electric power is supplied to the heater 13a. The thermocouple 13b is electrically connected to a temperature controller 15, which outputs to the power source 14 a control signal for controlling the electric power supplied to the heater 13a in accordance with an output from the thermocouple 13b. With this, the heater 13a and thus the susceptor 13 is maintained at a predetermined temperature.

At an upper portion of the process chamber 11, a plasma introducing structure 20 that introduces microwaves to the process chamber 11 from a microwave generator 24 is arranged. The plasma introducing structure 20 has a microwave transmission window 20A that is adjacently coupled to the process chamber 11 via a sealing member 11s and made of a ceramic material such as alumina, a Radial Line Slot Antenna 20B (referred to as antenna 20B below) closely connected to the microwave transmission window 20A, a disk-shaped holding plate 20C that holds the antenna 20B, and a wavelength shortening plate 20D interposed between the antenna 20B and the holding plate 20C.

The microwave transmission window 20A is made of a dielectric material such as a ceramic material including quartz, Al₂O₃, AlN, sapphire, SiN and the like, and serves as a window that introduces the microwaves into the process chamber 11. The antenna 20B is made from a copper plate or an aluminum plate whose surfaces are electroplated with gold or silver, and has plural slots 20Ba, 20Bb that penetrate the antenna 20B as shown in FIG. 1B. The wavelength shortening plate 20D is made of a dielectric material having a high dielectric constant such as Al₂O₃, SiO₂, AlN and Si₃N₄.

Referring back to FIG. 1A, a co-axial waveguide 21 is arranged in the center portion of the holding plate 20C. Specifically, an outer waveguide 21A of the co-axial waveguide 21 is connected to the holding plate 20C, and an inner waveguide 21B is connected to the antenna 20B through an opening formed in the center portion of the wavelength shortening plate 20D. In addition, the co-axial waveguide 21 is connected to the microwave generator 24 via a matching circuit 23. The microwave generator 24 generates microwaves having a frequency of 915 MHz, 2.45 GHz, or 8.3 GHz.

In this embodiment, the shower plate 31 is made of a ceramic material such as alumina or a metal such as Al and arranged below the microwave transmission window 20A. The shower plate 31 includes two independent gas supplying lines. One of the two gas supplying lines discharges a plasma generation gas, from which plasma is mainly generated, in an upward direction in the process chamber 11, and the other gas supplying line discharges a process gas, which is mainly used for processing the substrate S, in a downward direction in the process chamber 11.

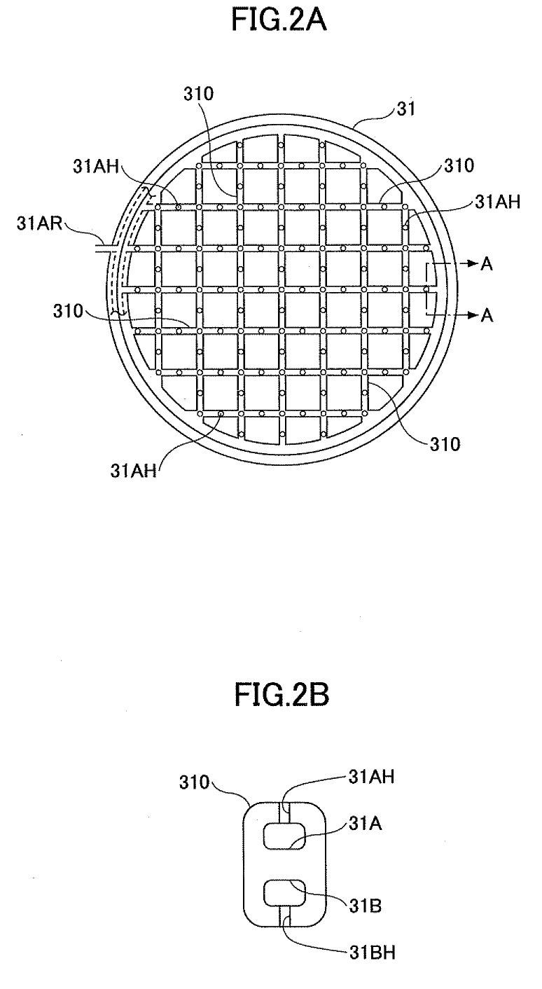

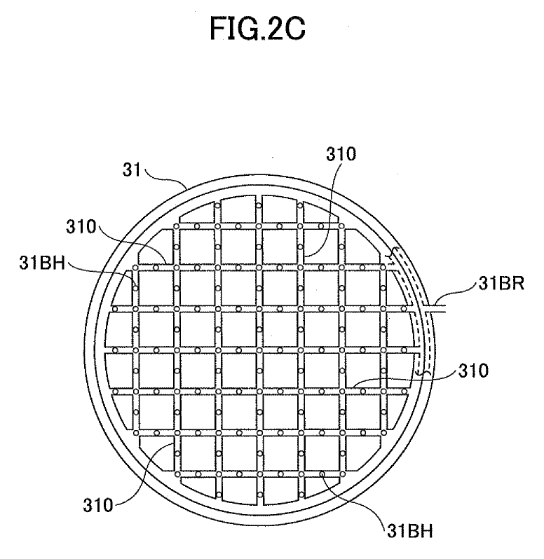

Next, referring to FIGS. 2A through 2C, the shower plate 31 is explained.

FIG. 2A illustrates one of the two faces of the shower plate 31, which faces the microwave transmission window 20A in the process chamber 11. The shower plate 31 has a grid-shaped member 310, as shown in FIG. 2A. FIG. 2B is a cross-sectional view of the grid-shaped member 310, which is taken along the line A-A in FIG. 2A. Referring to FIG. 2B, two gas passages 31A, 31B are provided inside the grid-shaped member 310. The gas passages 31A, 31B are arranged one above the other. The upper gas passage 31A is in gaseous communication with a gas discharging hole 31AH formed in the upper surface of the grid-shaped member 310. As shown in FIG. 2A, the plural gas discharging holes 31AH that are in gaseous communication with the gas passage 31A are arranged at predetermined intervals in the grid-shaped member 310. In addition, the gas passage 31A is in gaseous communication with a gas supplying line 61 via a gas port 31AR. The gas supplying line 61 is connected to a gas supplying source 60 provided outside the plasma processing apparatus 10. A gas supplied to the gas passage 31A from the gas supplying source 60 flows through the gas supplying line 61 (FIG. 1A), the gas port 31AR, and the gas passage 31A in this order, and is discharged toward the microwave transmission window 20A from the gas discharging holes 31AH in the process chamber 11 (FIG. 1A). The gas may be an inert gas (plasma generation gas) such as Ar and He, and is excited by the microwaves introduced into the process chamber 11 from the antenna 20B, thereby generating plasma in the process chamber 11.

On the other hand, the gas passage 31B in the shower plate 31 is in gaseous communication with a gas discharging hole 31BH formed in the lower surface of the grid-shaped member 310 (FIG. 2B). Referring to FIG. 2C that illustrates the other face of the grid-shaped member 310, which is opposite to the face illustrated in FIG. 2A, the plural gas discharging holes 31BH are arranged at predetermined intervals in the grid-shaped member 310. In addition, the gas passage 31B is in gaseous communication with a gas supplying line 62 via a gas port 31BR. The gas supplying line 62 is connected to the gas supplying source 60 (FIG. 1A). A gas supplied to the gas passage 31B from the gas supplying source 60 flows through the gas supplying line 62 (FIG. 1A), the gas port 31BR, and the gas passage 31B in this order, and is discharged toward the susceptor 13 from the gas discharging holes 31BH in the process chamber 11 (FIG. 1A). The gas may be a SiH₄ gas, which is decomposed by the microwave plasma generated in the process chamber 11, and thus a silicon film is deposited on the substrate S placed on the susceptor 13.

A distance between the shower plate 31 and the microwave transmission window 20A is preferably greater than or equal to a thickness of the plasma excitation region of the plasma generated in the process chamber 11. According to this, the shower plate 31 can be located outside the plasma excitation region, namely in the plasma diffusion region. Therefore, plasma damage to the shower plate 31 can be reduced. However, the shower plate 31 is not necessarily located outside the plasma diffusion region. This is because the electron temperature of the microwave plasma in the plasma diffusion region is sufficiently low, which causes substantially no damage to the shower plate 31.

Referring back to FIG. 1A, a mesh plate 50 is arranged between the shower plate 31 and the susceptor 13. The mesh plate 50 is supported by a supporting member 51 that extends from the bottom of the process chamber 11. The supporting member 51 is connected with a driving apparatus 52 that moves the supporting member 51 upward or downward, by which a distance of the mesh plate 50 from the upper surface of the susceptor 13 can be adjusted. The mesh plate 50 is made of an electrically conductive material, for example, a metal such as stainless steel and aluminum. In addition, the mesh plate 50 is connected to an electric power source 53 that applies voltage to the mesh plate 50 via the supporting member 51. With such a configuration, the mesh plate 50 can be maintained at a predetermined potential with respect to the process chamber 11. However, the mesh plate 50 may be grounded to earth, or separated (floated) from earth ground. In addition, a switch 53S is preferably provided as shown in FIG. 1A, so that the mesh plate 50 is selectively subject to voltage application, earth ground, or floating.

Next, a silicon film deposition method is explained that is carried out by using the plasma processing apparatus 10 configured above.

First, the distance between the mesh plate 50 and the susceptor 13 is adjusted by the driving apparatus 52. For example, this distance may be determined based on an inner pressure of the process chamber 11 and thus a mean free path of gas molecules in the process chamber 11. Qualitatively, when the inner pressure of the process chamber 11 is relatively high, the distance may be determined to be small, and when the inner pressure of the process chamber 11 is relatively low, the distance may be determined to be large. In addition, the susceptor 13 is heated by the temperature controller 15 and the electric power source 14, when necessary. A temperature of the susceptor 13 may be determined based on desired properties of the silicon film to be deposited. Moreover, a predetermined voltage may be applied to the mesh plate 50, when necessary.

Next, the substrate S is transferred into the process chamber 11 and placed on the susceptor 13 by a transfer mechanism (not shown). Then, the plasma generation gas, for example, Ar gas is supplied to the shower plate 31 from the gas supplying source 60 through the gas supplying line 61. The Ar gas is discharged in an upward direction toward the microwave transmission window 20A from the gas discharging holes 31AH of the shower plate 31. While the Ar gas is being supplied to the process chamber 11 in such a manner, the process chamber 11 is evacuated by the evacuation apparatus 41, and the inner pressure of the process chamber 11 is maintained at a predetermined pressure by the pressure control valve 43.

Next, the microwave generator 24 is activated to generate microwaves. The microwaves are introduced to the antenna 20B of the plasma introducing structure 20 through the matching circuit 23 and the inner waveguide 21B. Then, the microwaves propagate in a radial direction in the antenna 20B, are converted to have a predetermined wavelength by the wavelength shortening plate 20D, and are radiated into the process chamber 11 from the plural slots 20Ba, 20Bb of the antenna 20B through the microwave transmission window 20A. With this, the Ar gas discharged from the gas discharging holes 31AH is excited to produce active species, so that plasma is generated in the process chamber 11. The active species produced from the Ar gas diffuse or flow in a downward direction in the process chamber 11. When the active species pass through the mesh plate 50, ions and electrons are captured by the mesh plate 50 and disappear. Therefore, electrically neutral active species originated from the plasma generation gas are rather highly concentrated below the mesh plate 50 in the process chamber 11.

Then, SiH₄ gas as a source gas for the silicon film is supplied to the shower plate 31 from the gas supplying source 60 through the gas supplying line 62. This SiH₄ gas is discharged toward the susceptor 13 from the gas discharging holes 31BH of the shower plate 31. Before reaching the susceptor 13, SiH₄ molecules collide with the active species flowing downward through the shower plate 31, and thus active molecular species including SiH₃ and the like are produced from the SiH₄ molecules. Such active molecular species so produced from the SiH₄ reach the substrate S, and the silicon film is deposited on the substrate S.

In general, the film deposited on the substrate may be damaged and thus a quality of the film may be degraded in a plasma assisted film deposition apparatus because of bombardment of high energy ions and electrons in the plasma onto the film. In addition, when a silicon film that constitutes a thin film solar cell is deposited with SiH₄ gas as a source gas, it is known that the quality of the silicon film tends to be better if the silicon film is produced mainly from precursors such as SiH₃ and the like having low energy, which are intermediate species produced in the course of dissociation of SiH₄ molecules (see, “From Basics to Application of Thin Film Solar Cells—New Development of Environment friendly Solar Power Electric Generation”, Makoto KONAGAI, pp. 78-81, published March, 2001 by Ohmsha). Because the number of collisions between the gas molecules needs to be reduced in order to discourage dissociation, a distance between the substrate and the plasma is preferably decreased. However, the substrate S is more likely to be bombarded by the ions and electrons, and thus the film deposited on the substrate is damaged when the distance is small. In addition, because it is difficult to provide a uniform gas flow pattern when the distance is small, a film thickness uniformity may be degraded.

However, because the plasma-originated ions and electrons are captured by the mesh plate 50 arranged above the substrate S, the damage to the film deposited on the substrate is reduced, and unnecessary further dissociation of the SiH₄ molecules and the precursors such as SiH₃ is avoided in the plasma processing apparatus 10 according to this embodiment. Therefore, film quality degradation due to the high energy ions and electrons can be avoided, and thus a high quality film can be deposited from low energy precursors such as SiH₃.

An aperture opening of the mesh plate 50 (or a width W of the aperture opening) may be determined based on a mean free path of gas molecules in the process chamber 11 during film deposition carried out in the plasma processing apparatus 10, so that ions and electrons are more likely to hit the mesh plate 50. According to this, an increased number of ions and electrons are captured by the mesh plate 50, thereby further avoiding degradation of the film quality.

In addition, because the shower plate 31 is not necessarily arranged close to the susceptor 13 in the plasma processing apparatus 10 according to this embodiment, the distance between the shower plate 31 and the susceptor 13 may be arbitrarily adjusted in order to improve the film thickness uniformity.

Moreover, because the microwave plasma can inherently provide high plasma density, thereby increasing a density of source gas molecules, a film deposition rate of the silicon film on the substrate S cannot be largely reduced, even if ions and electrons are captured by the mesh plate 50 or silicon is deposited on the mesh plate 50.

Furthermore, because the plasma processing apparatus 10 according to the first embodiment has the electric power source 53 that applies a voltage to the mesh plate 50, an amount of the ions and electrons captured by the mesh plate 50 can be adjusted by adjusting the voltage applied to the mesh plate 50. With this, the properties and deposition rate of the silicon film deposited on the substrate S can be controlled.

In addition, because the plasma processing apparatus 10 has the driving apparatus 52 that can adjust a relative distance of the mesh plate 50 with respect to the susceptor 13, dissociation of the process gas and thus the properties and deposition rate of the film deposited on the substrate S1 can be controlled. Generally, the dissociation can be suppressed and thus a higher quality film can be deposited by making the relative distance small, whereas the dissociation is promoted and thus the deposition rate can be increased by making the relative distance large.

### A Second Embodiment

Next, a plasma processing apparatus according to a second embodiment of the present invention is explained. This plasma processing apparatus is different from the plasma processing apparatus 10 according to the first embodiment in that a temperature control system for controlling a temperature of the mesh plate 50 is provided. This plasma processing apparatus is mostly the same as the plasma processing apparatus 10 in other configurations. The following explanation focuses on the differences between this plasma processing apparatus and the plasma processing apparatus 10.

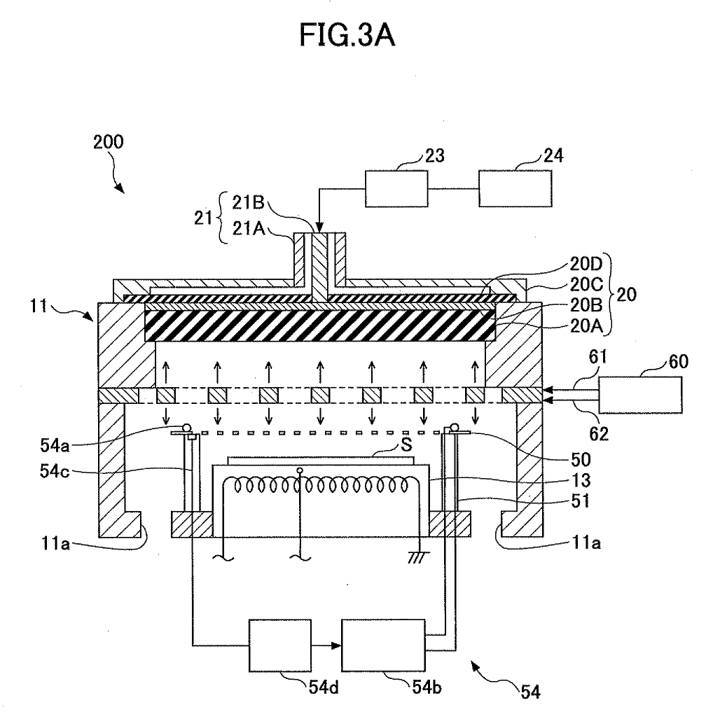

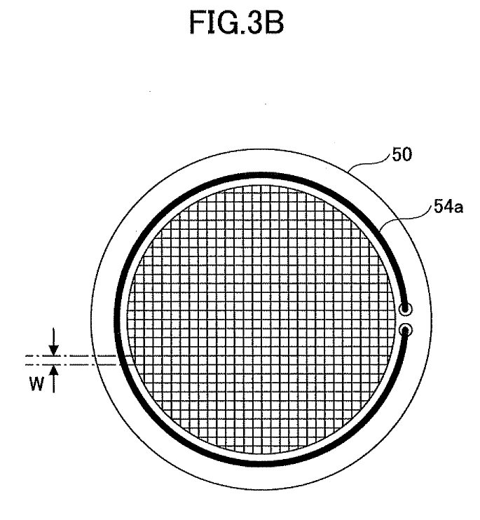

Referring to FIG. 3A, a plasma processing apparatus 200 according to the second embodiment of the present invention has a temperature control system 54. The temperature control system 54 has a heater 54a provided on the mesh plate 50, an electric power source 54b that supplies electricity to the heater 54a, a thermocouple 54c that extends to the mesh plate 50 through the supporting member 51 in order to measure a temperature of the mesh plate 50, and a temperature controller 54d that outputs a control signal for controlling the electricity supplied to the heater 54b in accordance with an output of the thermocouple 54c. For the sake of convenience, the electric power source 53, the evacuation apparatus 41, the duct 42, the pressure control valve 43, and the driving apparatus 52 are omitted in FIG. 3A.

Referring to FIG. 3B, the heater 54a is attached along a circumferential portion of the mesh plate 50. The heater 54a may be a sheath heater, a ribbon heater, and the like that have a corrosion resistance against the process gas and the like to be used in the plasma processing apparatus 200. Heat generated in the heater 54 by supplying electricity to the heater 54a radiates throughout the mesh plate 50, thereby heating the mesh plate 50 at a predetermined temperature. Specifically, the temperature of the mesh plate 50 is preferably in a range from about 200° C. through about 350° C., when a silicon film is deposited. According to the temperature range, silicon deposition on the mesh plate 50 can be avoided, which in turn can avoid a reduction of the deposition rate of the silicon film on the substrate S. In addition, when the temperature of the mesh plate 50 is 200° C. or more, it is expected that high order silanes are not likely to be produced, thereby contributing to improved properties of the silicon film deposited on the substrate S.

In addition, because the mesh plate 50 in the plasma processing apparatus 200 has the same configuration as the mesh plate 50 in the plasma processing apparatus 10 according to the first embodiment except in that the temperature of the mesh plate 50 can be controlled, the mesh plate 50 in the second embodiment can capture the ions and electrons. Therefore, the same effect as the first embodiment can be demonstrated by the plasma processing apparatus 200 according to the second embodiment.

### A Third Embodiment

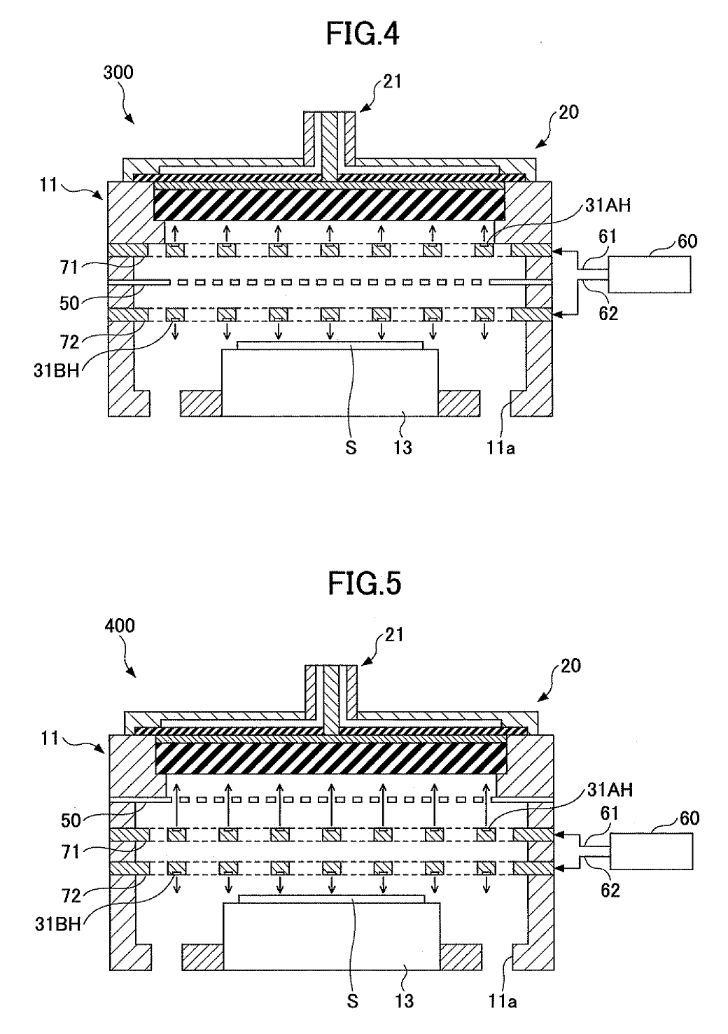

Next, a plasma processing apparatus according to a third embodiment of the present invention is explained. FIG. 4 is a schematic view illustrating a plasma processing apparatus 300 according to the third embodiment of the present invention. As is understood by comparing FIG. 4 with FIG. 1, the plasma processing apparatus 300 according to the third embodiment is different from the plasma processing apparatus 10 according to the first embodiment in terms of a configuration of a gas supplying portion (e.g., the shower plate) and a positional relationship between the gas supplying portion and the mesh plate 50. This plasma processing apparatus 300 is mostly the same as the plasma processing apparatus 10 in other configurations. The following explanation focuses on the differences between this plasma processing apparatus 200 and the plasma processing apparatus 10 of the other configurations.

Referring to FIG. 4, the plasma processing apparatus 300 has a shower plate 71 that discharges the plasma generation gas (e.g., Ar gas) toward the plasma introducing structure 20, and another shower plate 72 that discharges the process gas (e.g., SiH₄ gas in the case of silicon film deposition) toward the susceptor 13. The shower plate 71 is arranged between the plasma introducing structure 20 and the mesh plate 50, and the shower plate 72 is arranged between the mesh plate 50 and the susceptor 13.

The shower plates 71, 72 are grid-shaped, and may have substantially the same plan view shape as the shower plate 31 in the first embodiment. However, the shower plates 71, 72 are different from the shower plate 31 in that the shower plates 71, 72 have only one gas supplying line whereas the shower plate 31 has the two gas supplying lines. Specifically, the shower plate 71 has configurations corresponding to the gas passage 31A, the plural gas discharging holes 31AH, and the gas port 31AR in the shower plate 31, and the shower plate 72 has configurations corresponding to the gas passage 31B, the plural gas discharging holes 31BH, and the gas port 31BR in the shower plate 31.

According to such configurations, the plasma generation gas is discharged upward from the gas discharging holes 31AH, and excited by the microwaves introduced into the process chamber 11 from the plasma introducing structure 20. The excited plasma generation gas (active species) diffuses or flows downward in the process chamber 11. When the active species pass through the mesh plate 50, the ions and electrons are captured by the mesh plate 50 and disappear. Therefore, electrically neutral species originated from the plasma generation gas are highly concentrated below the mesh plate 50.

On the other hand, the process gas (e.g., SiH₄ gas) is discharged downward from the gas discharging holes 31BH of the shower plate 72 arranged below the mesh plate 50. Process gas molecules collide with the active species that are diffusing or flowing downward from above before reaching the substrate S on the susceptor 13, and thus molecular species such as SiH₃ are generated. Such molecular species originated from SiH₄ generated in such a manner reach the substrate S, and thus the silicon film is deposited on the substrate S.

Because the mesh plate 50 can capture the ions and electrons in the plasma processing apparatus 300 according to the third embodiment, a concentration of the neutral molecular species (radicals) can be relatively increased in a space between the mesh plate 50 and the susceptor 13. Therefore, the same effect as explained above can be demonstrated also in this embodiment.

### A Fourth Embodiment

Next, a plasma processing apparatus according to a fourth embodiment of the present invention is explained.

FIG. 5 is a schematic view illustrating a plasma processing apparatus 400 according to the fourth embodiment. As is understood by comparing FIG. 5 with FIG. 4, the plasma processing apparatus 400 according to the fourth embodiment is different from the plasma processing apparatus 300 according to the third embodiment in terms of a positional relationship between the shower plate 71 and the mesh plate 50, and the same as the plasma processing apparatus 300 in other configurations. The following explanation focuses on such a difference.

Referring to FIG. 5, the mesh plate 50 is arranged between the plasma introducing structure 20 and the shower plate 71 in the plasma processing apparatus 400 according to the fourth embodiment. A distance between the plasma introducing structure 20 and the shower plate 71 is preferably more than or equal to a thickness of the plasma excitation region of the plasma generated in the process chamber 11. With this, the mesh plate 50 may be located outside the plasma excitation region, namely in the plasma diffusion region. Therefore, plasma damage to the mesh plate 50 can be reduced. However, the mesh plate 50 is not necessarily located outside the plasma diffusion region. This is because the electron temperature of the microwave plasma in the plasma diffusion region is sufficiently low, which causes substantially no damage to the mesh plate 50.

According to such a configuration, the plasma generation gas is discharged upward from the gas discharging holes 31AH, passes through the mesh plate 50 to reach a vicinity of the plasma introducing structure 20, and is excited by the microwaves introduced to the process chamber 11 from the plasma introducing structure 20, which in turn generates the microwave plasma. The plasma-originated active species, ions, and electrons flow downward to pass through the mesh plate 50. When passing through the mesh plate 50, the ions and electrons are captured by the mesh plate 50 and disappear. Therefore, mainly the neutral species such as radicals can flow further downward. On the other hand, the process gas is discharged downward from the gas discharging holes 31BH of the shower plate 72, and the process gas molecules collide with the neutral species flowing downward from above, by which the molecular species such as SiH₃ are generated. Such molecular species reach the substrate S on the susceptor 13, and thus the silicon film is deposited on the substrate S.

Because the mesh plate 50 can capture the ions and electrons in the plasma processing apparatus 400 according to the fourth embodiment, a concentration of the neutral molecular species (radicals) can be relatively increased in a space between the mesh plate 50 and the susceptor 13. Therefore, the same effect as explained above can be demonstrated also in this embodiment.

### A Fifth Embodiment

Next, a plasma processing apparatus according to a fifth embodiment of the present invention is explained.

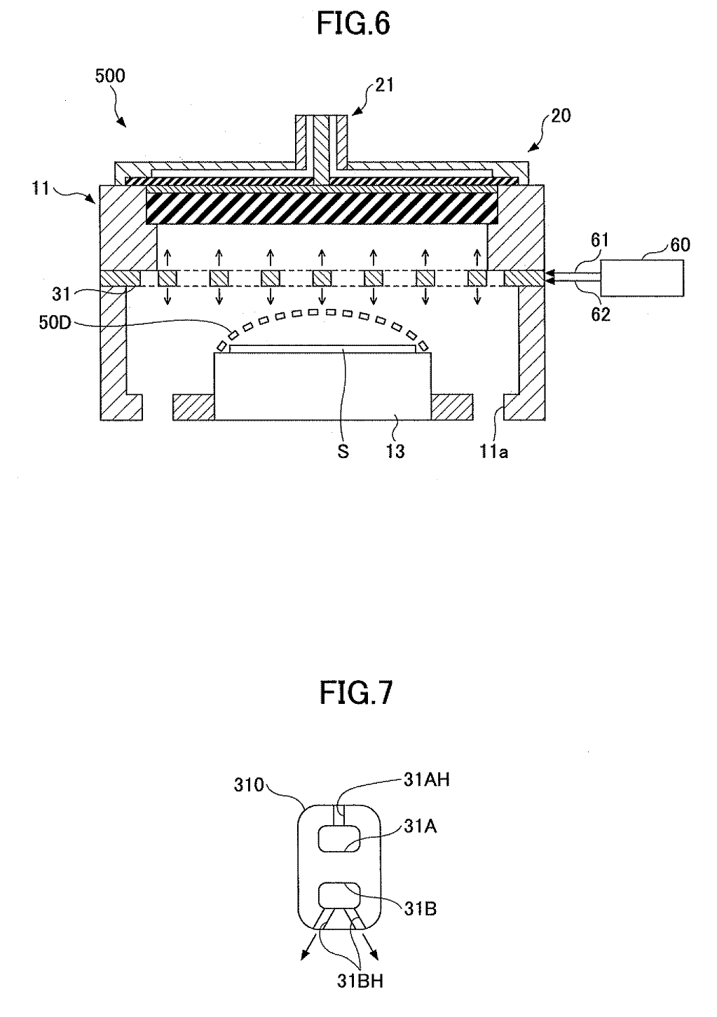

FIG. 6 is a schematic view illustrating a plasma processing apparatus 500 according to the fifth embodiment. As is understood by comparing FIG. 5 with FIG. 1, the plasma processing apparatus 500 according to the fifth embodiment is different from the plasma processing apparatus 10 according to the first embodiment in that a mesh dome 50D instead of the mesh plate 50 is provided in the plasma processing apparatus 500. This plasma processing apparatus 500 is mostly the same as the plasma processing apparatus 300 in other configurations. The following explanation focuses on the differences between the plasma processing apparatus 500 and the plasma processing apparatus 300 shown in other configurations.

Referring to FIG. 6, the mesh dome 50D is configured by curving a mesh made of an electrically conductive material, and placed on the susceptor 13. In addition, the mesh dome 50D has a diameter larger than the diameter of the substrate S, and is arranged over the substrate S on the susceptor 13. An aperture opening of the mesh dome 50D may be determined in the same manner as the aperture opening of the mesh plate 50. Moreover, a substantial distance between the mesh dome 50D and the substrate S placed on the susceptor 13 can be adjusted by arbitrarily adjusting a curvature of the dome shape of the mesh dome 50D.

The mesh dome 50D may be placed on the susceptor 13 along with the substrate S at the same time when the substrate S is placed on the susceptor 13 by a predetermined transfer mechanism. In addition, the mesh dome 50D can be heated along with the substrate S by heating the susceptor 13 because the mesh dome 50D contacts the susceptor 13. Therefore, the temperature control system 54 (FIG. 3) in the second embodiment is not necessary in the fifth embodiment.

The ions and electrons can be captured even by the mesh dome 50D in the plasma processing apparatus 500 according to the fifth embodiment. The same effect produced by the plasma processing apparatus 10 according to the first embodiment can be demonstrated also in this embodiment.

Although the present invention has been explained with reference to several embodiments, the present invention is not limited to those embodiments, but may be modified or altered within the scope of the accompanying claims.

For example, while the mesh plate 50 and the mesh dome 50D are made of an electrically conductive material, for example, a metal such as stainless steel and aluminum in the above embodiments, the mesh plate 50 and the mesh dome 50D may be made of a nonconductive material, for example, a ceramic material such as alumina and AlN in other embodiments. Even if the mesh plate 50 and the mesh dome 50D do not have electrical conductivity, the ions and electrons can be captured when colliding with the mesh plate 50 and the mesh dome 50D, so that the same effect can be demonstrated through a reduction of the ions and electrons.

In addition, two or more mesh plates may be provided in the plasma processing apparatus in other embodiments. With this, the ions and electrons may be effectively captured.

Moreover, the two or more embodiments explained above may be combined. For example, the temperature control system 54 provided in the plasma processing apparatus 200 according to the second embodiment may be provided in the plasma processing apparatuses 300, 400, and 500 according to the corresponding embodiments. With this, the mesh plate 50 may be maintained at an appropriate temperature in the plasma processing apparatuses 300, 400, and 500.

Furthermore, although the shower plate 31 is configured to include two independent gas supplying lines so that the plasma generation gas is discharged upward from one of the two gas lines and the process gas is discharged downward from the other gas line in the first embodiment, the shower plate 31 is not always configured in this manner. For example, two shower plates (e.g., the shower plates 71, 72) having corresponding gas supplying lines are prepared instead of the shower plate 31, and may be arranged between the plasma introducing structure 20 and the mesh plate 50 so that the plasma generation gas is discharged upward from one of the two shower plates and the process gas is discharged downward from the other shower plate. In other words, the shower plates 71, 72 may be provided instead of the shower plate 31 in the plasma processing apparatus 11 according to the first embodiment so that the shower plate 71, the shower plate 72, and the mesh plate 50 are arranged in this order in a direction from the plasma introducing structure 20 to the susceptor 13.

Although the shower plates 31, 71, 72 in the plasma processing apparatuses 10, 200, 300, 400, 500 have a grid-shape, they may also have a concentric shape or a spiral shape.

In addition, the shower plate 31 in the plasma processing apparatus 10 (FIG. 1) according to the first embodiment is prepared and arranged, instead of the shower plates 71, 72, between the mesh plate 50 and the susceptor 13 in the plasma processing apparatus 400 (FIG. 5) according to the fourth embodiment of the present invention.

Moreover, although the shower plates 31, 71, 72 are employed in the plasma processing apparatuses 10, 200, 300, 400, 500, gas nozzles may be inserted into the process chamber 11 through a side wall of the process chamber 11, so that the plasma generation gas and the process gas are introduced into the process chamber 11 through the gas nozzles instead of the shower plates 31, 71, 72. In this case, a positional relationship between the gas nozzles and the mesh plate 50 is the same as the positional relationship between the shower plates 31, 71, 72 and the mesh plate 50. In addition, when the gas nozzles are used, a pressure differentiating portion may be arranged between the plasma introducing structure 20 and the susceptor 13 so that a relatively high pressure difference is produced between the upper space including the plasma introducing structure 20 and the lower space including the susceptor 13, in order to uniformly guide the gasses from the gas nozzles to the substrate S.

Furthermore, while the gas discharging holes 31BH of the shower plate 31 are open vertically downward, which is directly opposite to the gas discharging holes 31AH, two types of the gas discharging holes 31BH that are in gaseous communication with the gas passage 31B may be formed so that these gas discharging holes 31BH are inclined in predetermined directions with respect to the vertical direction, as shown in FIG. 7. With this, because the process gas is discharged in two directions inclined with respect to the vertical direction, the process gas concentration can be uniform in the process chamber 11, thereby improving a thickness uniformity of the film deposited on the substrate S. In addition, these gas discharging holes 31BH may be formed in the shower plate 72.

Although the two different gas supplying portions are provided for the plasma generation gas and the process gas in the above embodiments, only the gas supplying portion for the process gas may be provided and only the process gas may be supplied to the process chamber 11 when the plasma can be generated from the process gas by microwaves.

While the mesh dome 50D has a shape of a round dome in the fifth embodiment, the mesh dome 50D may have a plateau in the upper portion of the mesh dome 50D. Alternatively, the mesh dome 50D may have a concave shaped apex portion, as long as the apex portion does not contact the substrate S. In addition, the mesh dome 50D may be supported by a supporting member on the susceptor 13 so that the mesh dome 50D does not contact the substrate S.

Furthermore, the mesh dome 50D may be provided with a heater so that the mesh dome 50D is temperature-controlled by a temperature control system. This heater may be configured in the same manner as the heater 54a in the second embodiment. In this case, it is preferable that the mesh dome 50D is not placed directly on the susceptor 13 but supported by a predetermined supporting member so that the temperature of the mesh dome 50D can be controlled independently from the temperature of the susceptor 13. This supporting member is preferably made of a material having a low thermal conductivity in order to sufficiently differentiate the temperatures of the mesh dome 50D and the susceptor 13. The temperature of the mesh dome 50D may be higher than the temperature of the inner wall of the process chamber 11. In addition, the mesh dome 50D having a higher temperature than the susceptor 13 is preferable in that film deposition onto the mesh dome 50D can be reduced.

The antenna 20B is not limited to the Radial Line Slot Antenna, but may be other planar antennas. In addition, a waveguide may be used instead of the antenna 20B, as long as microwaves can be introduced to the process chamber 11.

While the plasma assisted film deposition apparatus for depositing a silicon film as a plasma processing apparatus is exemplified in the above embodiments, the plasma processing apparatus according to an embodiment of the present invention may be a plasma assisted film deposition apparatus for depositing a silicon oxide film or silicon nitride film. In addition, the plasma processing apparatus according to an embodiment of the present invention may be a surface modification processing apparatus for, for example, oxidizing a surface of the silicon film into a surface silicon oxide layer, or nitriding a surface of the silicon film into a surface silicon nitride layer. Such a plasma processing apparatus can preferably be used to form a gate insulator because plasma damage is sufficiently reduced. Moreover, the plasma processing apparatus according to an embodiment of the present invention may be a plasma etching apparatus where an etching gas is used as the process gas. While there is a problem in a general plasma etching apparatus in that the underlying after etching may be damaged by the ions and electrons in the plasma, such plasma damage can be greatly reduced in the plasma processing apparatus according to an embodiment of the present invention because the ions and electrons can be captured by the mesh plate 50.

The present application is based on Japanese priority application No. 2008-166347 filed Jun. 25, 2008, the entire contents of which are hereby incorporated herein by reference.

What is claimed is:

1. A microwave plasma processing apparatus comprising:
a process chamber whose inside may be maintained at a reduced pressure;
a susceptor that is provided in the process chamber and holds a substrate;
a gas supplying portion configured to supply a gas to the process chamber;
a microwave generating portion that generates microwaves;
a plasma introducing portion that is arranged to oppose the susceptor and introduces the microwaves generated by the microwave generating portion to the process chamber; and
a mesh member arranged between the plasma introducing portion and the susceptor.

2. The microwave plasma processing apparatus as recited in claim 1, further comprising a temperature adjusting portion that adjusts a temperature of the mesh member.

3. The microwave plasma processing apparatus as recited in claim 1, further comprising an electric power source that applies a voltage to the mesh member.

4. The microwave plasma processing apparatus as recited in claim 1, wherein the gas supplying portion includes
a first gas passage formed inside the gas supplying portion;
plural first gas discharging holes that are in communication with the first gas passage and open in a first direction;
a second gas passage formed inside the gas supplying portion, the second gas passage being separated from the first gas passage; and
plural second gas discharging holes that are in communication with the second gas passage and open in a second direction different from the first direction.

5. The microwave plasma processing apparatus as recited in claim 1, wherein the mesh member is arranged between the gas supplying portion and the susceptor.

6. The microwave plasma processing apparatus as recited in claim 1, wherein the mesh member is arranged between the plasma introducing portion and the gas supplying portion.

7. The microwave plasma processing apparatus as recited in claim 1, wherein the gas supplying portion comprises a first member and a second member,
wherein the first member includes
a first gas passage formed inside the first member; and
plural first gas discharging holes that are in communication with the first gas passage and open in a first direction, and
wherein the second member includes
a second gas passage formed inside the second member; and
plural second gas discharging holes that are in communication with the second gas passage and open in a second direction different from the first direction.

8. The microwave plasma processing apparatus as recited in claim 7, wherein the first member, the mesh member, and the second member are arranged in this written order in a direction from the plasma introducing portion to the susceptor between the plasma introducing portion and the susceptor.

9. The microwave plasma processing apparatus as recited in claim 7, wherein the mesh member, the first member, and the second member are arranged in this written order in a direction from the plasma introducing portion to the susceptor between the plasma introducing portion and the susceptor.

10. The microwave plasma processing apparatus as recited in claim 7, wherein the first member, the second member, and the mesh member are arranged in this written order in a direction from the plasma introducing portion to the susceptor between the plasma introducing portion and the susceptor.

11. The microwave plasma processing apparatus as recited in claim 1, wherein the mesh member is placed on the susceptor so that the mesh member does not contact the substrate placed on the susceptor.
